(19) United States
(12) Patent Application Publication
(10) Pub. No.: US 2020/0286869 A1
(43) Pub. Date: Sep. 10, 2020

(54) DISPLAY APPARATUS AND MANUFACTURING METHOD FOR THE SAME

(71) Applicant: Qisda Corporation, Taoyuan City (TW)

(72) Inventors: Yi-Cheng KUO, Taoyuan County (TW); Meng-Wei LIN, Taoyuan City (TW); Chih-Chieh SU, Hsinchu County (TW)

(73) Assignee: Qisda Corporation, Taoyuan City (TW)

(21) Appl. No.: 16/809,695

(22) Filed: Mar. 5, 2020

(30) Foreign Application Priority Data
Mar. 8, 2019 (CN) 201910178295.4

(51) Int. Cl. H01L 25/075; H05K 5/00; H05K 3/36; H05K 1/14

(52) U.S. Cl. CPC H01L 25/0753; H05K 5/0017; H05K 1/142; H05K 3/368; H05K 5/0021

(57) ABSTRACT

A display apparatus and a manufacturing method for the same. The display apparatus includes a first display device and a second display device. The first display device includes a first circuit board, first display pixels and a first opaque rubber. The first display pixels are electrically connected on the first circuit board. The first opaque rubber includes a first outer border rubber portion outside the first display pixels; and a first spacer rubber portion in a gap space between the first display pixels. The second display device includes a second circuit board, second display pixels on the second circuit board and a second opaque rubber including a second outer border rubber portion outside the second display pixels. The first display device and the second display device are stitched together. The first outer border rubber portion and the second outer border rubber portion are faced and adjacent to each other.

This application claims the benefit of People's Republic of China application Serial No. 201910178295.4, filed Mar. 8, 2019, the subject matter of which is incorporated herein by reference.

### BACKGROUND OF THE INVENTION

### Field of the Invention

The present disclosure relates to a display apparatus and a manufacturing method for the same, and more particularly to a display apparatus having a stitching seam and a manufacturing method for the same.

### Description of the Related Art

Currently, light emitting diode (LED) display apparatuses are modularized and then stitched into a large display apparatus, a stitching seam of which is not apparent when watching with a long distance. The stitching seam becomes more apparent as the watching distance decreases. In particular, when the resolution for a LED display apparatus is increased, a gap distance for each pixel is decreased. The stitching seam in the high-resolution display apparatus is also more apparent.

### SUMMARY OF THE INVENTION

The present disclosure relates to a display apparatus and a manufacturing method for the same. A display effect of the display apparatus can be improved.

An embodiment of the present disclosure provides a display apparatus, comprising a first display device and a second display device. The first display device comprises a first circuit board, first display pixels and a first opaque rubber. The first display pixels are electrically connected on the first circuit board. The first opaque rubber comprises a first outer border rubber portion and a first spacer rubber portion. The first spacer rubber portion is in a gap space between the first display pixels. The first outer border rubber portion is outside the first display pixels. The second display device comprises a second circuit board, second display pixels and a second opaque rubber. The second display pixels are electrically connected on the second circuit board. The second opaque rubber comprises a second outer border rubber portion. The second outer border rubber portion is outside the second display pixels. The first display device and the second display device are stitched together. The first outer border rubber portion and the second outer border rubber portion are faced and adjacent to each other. The first spacer rubber portion, the first outer border rubber portion and the second outer border rubber portion have the same height.

Another embodiment of the present disclosure provides a display apparatus, comprising a first display device and a second display device. The first display device comprises a first circuit board, first display pixels, and a first opaque rubber. The first display pixels are electrically connected on the first circuit board. The first opaque rubber comprises a first outer border rubber portion and a first spacer rubber portion. The first spacer rubber portion is in a gap space between the first display pixels. The first outer border rubber portion is outside the first display pixels. The second display device comprises a second circuit board, second display pixels, and a second opaque rubber. The second display pixels are electrically connected on the second circuit board. The second opaque rubber comprises a second outer border rubber portion. The second outer border rubber portion is outside the second display pixels. The first display device and the second display device are stitched together. The first outer border rubber portion and the second outer border rubber portion are faced and adjacent to each other. The first circuit board and the second circuit board have a stitching seam therebetween. There is no adhesive rubber at the stitching seam.

A yet another embodiment of the present disclosure provides a manufacturing method for a display apparatus, comprising the following steps. A first display device is provided. The first display device comprises a first circuit board, first display pixels and a first opaque rubber. The first display pixels are on the first circuit board. The first opaque rubber is on the first circuit board. The first opaque rubber comprises a first outer border rubber portion and a first spacer rubber portion. The first spacer rubber portion is in a gap space between the first display pixels. The first outer border rubber portion is outside the first display pixels. A second display device is provided. The second display device comprises a second circuit board, second display pixels, and a second opaque rubber. The second display pixels are on the second circuit board. The second opaque rubber comprises a second outer border rubber portion. The second outer border rubber portion is outside the second display pixels. The first display device and the second display device are stitched together. The first outer border rubber portion and the second outer border rubber portion are faced and adjacent to each other. The first circuit board and the second circuit board are faced and adjacent to each other.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 to FIG. 6 illustrate a manufacturing method for a display apparatus according to an embodiment.

FIG. 7 illustrates a cross-section view of a display apparatus according to another embodiment.

### DETAILED DESCRIPTION OF THE INVENTION

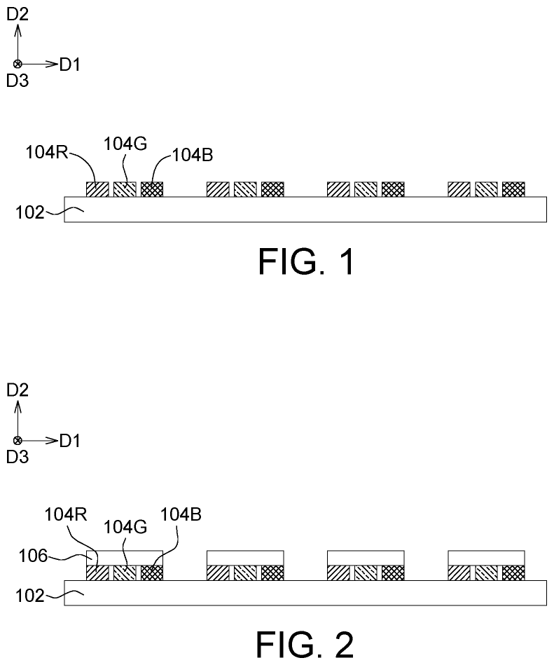

FIG. 1 to FIG. 6 illustrate a manufacturing method for a display apparatus according to an embodiment.

Referring to FIG. 1, light emitting units, such as light emitting units 104R, light emitting units 104G, and light emitting units 104B, are disposed on a first circuit board 102. The light emitting unit may comprise a light emitting diode. In an embodiment, the light emitting unit 104R is a red light emitting diode, the light emitting unit 104G is a green light emitting diode, and the light emitting unit 104B is a blue light emitting diode. In an embodiment, the light emitting units may be micro light emitting diodes disposed on the first circuit board 102 by a mass transferring method. The micro light emitting diode may have a diagonal length of 1 μm to 100 μm. For example, the light emitting unit 104R, the light emitting unit 104G, and the light emitting unit 104B may be electrically connected to the first circuit board 102 through a wire bonding method. It is described that in the present disclosure the first circuit board 102 is not limited to any material, and may be a glass circuit board, a plastic circuit board, and so on, for example.

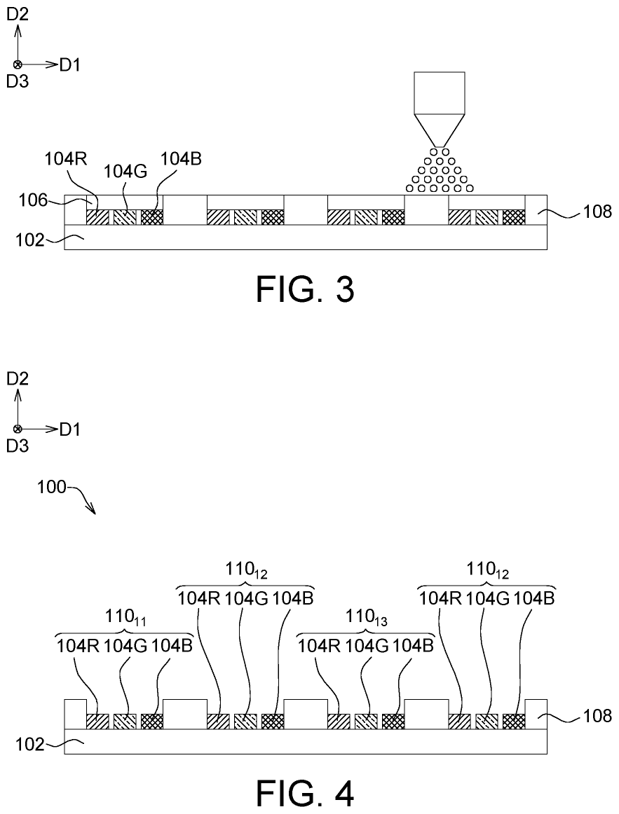

Referring to FIG. 2, a mask 106 may be formed on the light emitting unit 104R, the light emitting unit 104G, and the light emitting unit 104B.

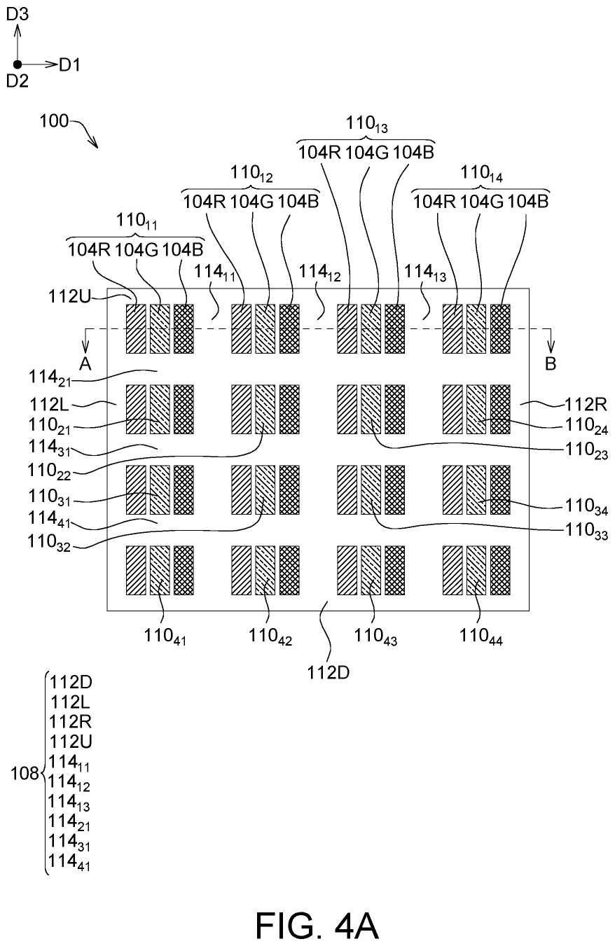

Referring to FIG. 3, a first opaque rubber 108 may be disposed on a portion of the first circuit board 102 not covered by the mask 106. The first opaque rubber 108 may be formed by disposing a curable rubber material by a spraying method, and then performing a curing step. The first opaque rubber 108 may be formed by other suitable methods, such as a coating method, an injecting method, etc. In an embodiment, the first opaque rubber 108 may comprise a black rubber or a grey rubber, for example. For example, a material for the first opaque rubber 108 may comprise a silicone resin such as silicone, or an encapsulating material such as an epoxy resin, or other suitable materials.

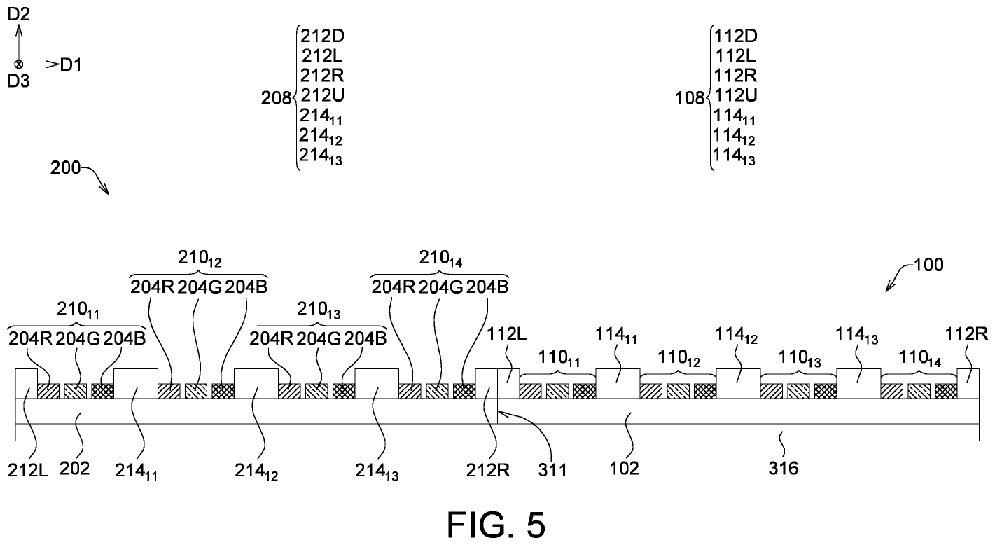

Referring to FIG. 4, the mask 106 is removed so as to form a first display device 100.

FIG. 4A shows a plan view of the first display device 100 according to an embodiment. FIG. 4 may be a cross-section view drawn along a AB section line in FIG. 4A. Referring to FIG. 4 and FIG. 4A, the first display device 100 comprises first display pixels, such as a first display pixel 110₁₁, a first display pixel 110₁₂, a first display pixel 110₁₃, a first display pixel 110₁₄, a first display pixel 110₂₁, a first display pixel 110₂₂, a first display pixel 110₂₃, a first display pixel 110₂₄, a first display pixel 110₃₁, a first display pixel 110₃₂, a first display pixel 110₃₃, a first display pixel 110₃₄, a first display pixel 110₄₁, a first display pixel 110₄₂, a first display pixel 110₄₃, and a first display pixel 110₄₄. Each of the first display pixels may comprise the light emitting unit 104R, the light emitting unit 104G, and the light emitting unit 104B.

The first display pixels may be surrounded and framed by the first opaque rubber 108. The first opaque rubber 108 may comprise a first outer border rubber portion. The first outer border rubber portion is outside the first display pixels. Referring to FIG. 4A, for example, a first outer border rubber portion 112U is on an upper side of the light emitting units 104R, the light emitting units 104G, and the light emitting units 104B of the first display pixel 110₁₁, the first display pixel 110₁₂, the first display pixel 110₁₃, and the first display pixel 110₁₄ arranged in order along a first direction D1. A first outer border rubber portion 112L is on a left side of the light emitting units 104R of the first display pixel 110₁₁, the first display pixel 110₂₁, the first display pixel 110₃₁, and the first display pixel 110₄₁ arranged in order along a third direction D3. A first outer border rubber portion 112R is on a right side of the light emitting units 104B of the first display pixel 110₁₄, the first display pixel 110₂₄, the first display pixel 110₃₄, and the first display pixel 110₄₄ arranged in order along the third direction D3. A first outer border rubber portion 112D is on a lower side of the light emitting units 104R, the light emitting units 104G, and the light emitting units 104B of the first display pixel 110₄₁, the first display pixel 110₄₂, the first display pixel 110₄₃, and the first display pixel 110₄₄ arranged in order along the first direction D1.

The first opaque rubber 108 may also comprise first spacer rubber portions. The first spacer rubber portion is in a gap space between the first display pixels. For example, a first spacer rubber portion 114₁₁ is on the first circuit board 102 between the light emitting unit 104B of the first display pixel 110₁₁ and the light emitting unit 104R of the first display pixel 110₁₂. A first spacer rubber portion 114₁₂ is on the first circuit board 102 between the light emitting unit 104B of the first display pixel 110₁₂ and the light emitting unit 104R of the first display pixel 110₁₃. A first spacer rubber portion 114₁₃ is on the first circuit board 102 between the light emitting unit 104B of the first display pixel 110₁₃ and the light emitting unit 104R of the first display pixel 110₁₄. A first spacer rubber portion 114₂₁ is on the first circuit board 102 between the first display pixel 110₁₁ and the first display pixel 110₂₁. A first spacer rubber portion 114₃₁ is on the first circuit board 102 between the first display pixel 110₂₁ and the first display pixel 110₃₁. A first spacer rubber portion 114₄₁ is on the first circuit board 102 between the first display pixel 110₃₁ and the first display pixel 110₄₁. In an embodiment, the first spacer rubber portions may have the same width. For example, widths of the first spacer rubber portion 114₁₁, the first spacer rubber portion 114₁₂, and the first spacer rubber portion 114₁₃ in the first direction D1 may be identical to each other. Widths of the first spacer rubber portion 114₂₁, the first spacer rubber portion 114₃₁, and the first spacer rubber portion 114₄₁ in the third direction D3 may be identical to each other. The characteristic and the disposition for the other first spacer rubber portions can be deduced by analogy.

In an embodiment, the first outer border rubber portion and the first spacer rubber portion of the first opaque rubber 108 may have the same height. Otherwise, an upper surface of the first outer border rubber portion and an upper surface of the first spacer rubber portion may be at the same height level. In an embodiment, a width of the first outer border rubber portion may be one-half of a width of the first spacer rubber portion. For example, a width of the first outer border rubber portion 112L in the first direction D1 may be one-half of a width of the first spacer rubber portion 114₁₁ in the first direction D1. In an embodiment, a width of the first outer border rubber portion 112U in the third direction D3 may be one-half of a width of the first spacer rubber portion 114₂₁ in the third direction D3.

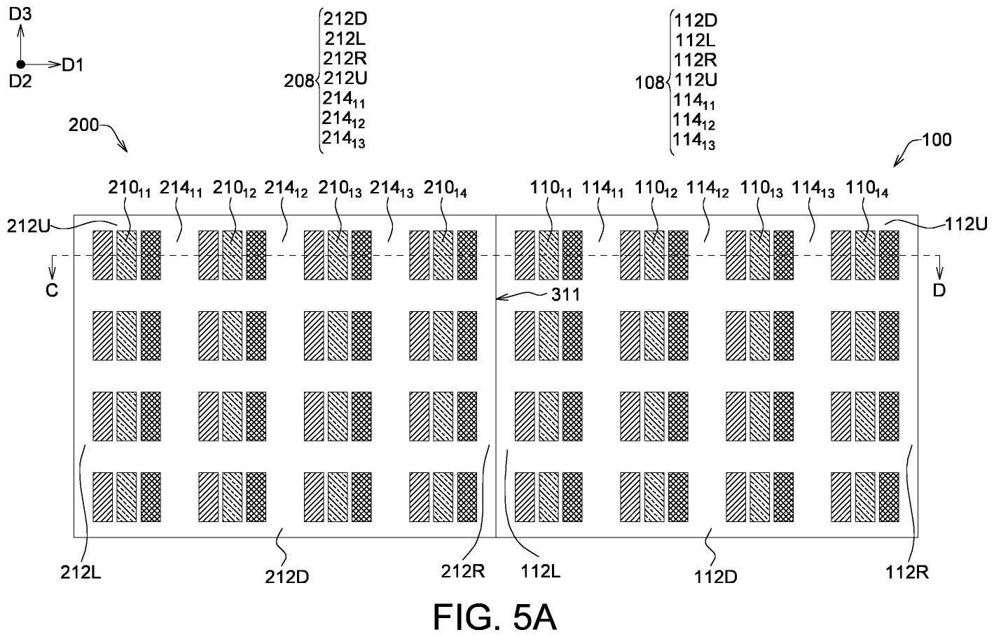

Referring to FIG. 5, a second display device 200 is provided. The second display device 200 may comprise a second circuit board 202, a second opaque rubber 208, and second display pixels. For example, the second display pixels comprise a second display pixel 210₁₁, a second display pixel 210₁₂, a second display pixel 210₁₃, and a second display pixel 210₁₄ arranged in order along the first direction D1. Each of the second display pixels may comprise a light emitting unit 204R, a light emitting unit 204G, and a light emitting unit 204B. In an embodiment, the light emitting unit 204R is a red light emitting diode, the light emitting unit 204G is a green light emitting diode, and the light emitting unit 204B is a blue light emitting diode. In an embodiment, the light emitting units may be micro light emitting diodes disposed on the second circuit board 202 by a mass transferring method. In an embodiment, the light emitting units of the second display pixels may be electrically connected onto the second circuit board 202 through a wire bonding method. It is described that in the present disclosure the second circuit board 202 is not limited to any material, and may be a glass circuit board, a plastic circuit board, and so on, for example.

The second opaque rubber 208 comprises a second outer border rubber portion 212L, a second outer border rubber portion 212R, a second outer border rubber portion 212U, a second outer border rubber portion 212D and second spacer rubber portions. The second outer border rubber portion 212L, the second outer border rubber portion 212R, the second outer border rubber portion 212U, and the second outer border rubber portion 212D are outside the second display pixels. For example, a second spacer rubber portion 214₁₁ is on the second circuit board 202 between the light emitting unit 204B of the second display pixel 210₁₁ and the light emitting unit 204R of the second display pixel 210₁₂. A second spacer rubber portion 214₁₂ is on the second circuit board 202 between the light emitting unit 204B of the second display pixel 210₁₂ and the light emitting unit 204R of the second display pixel 210₁₃. A second spacer rubber portion 214₁₃ is on the second circuit board 202 between the light emitting unit 204B of the second display pixel 210₁₃ and the light emitting unit 204R of the second display pixel 210₁₄. In an embodiment, the second spacer rubber portions may have the same width. For example, the second spacer rubber portion 214₁₁, the second spacer rubber portion 214₁₂, and the second spacer rubber portion 214₁₃ may have the same width in the first direction D1. The characteristic and the disposition for the other second spacer rubber portions can be deduced by analogy.

In an embodiment, the second outer border rubber portion and the second spacer rubber portion of the second opaque rubber 208 may have the same height in a second direction D2. Otherwise, an upper surface of the second outer border rubber portion and an upper surface of the second spacer rubber portion may be at the same height level. Upper surfaces of the second outer border rubber portion and the second spacer rubber portion of the second opaque rubber 208 are above upper surfaces of the light emitting unit 204R, the light emitting unit 204G, and the light emitting unit 204B (such as the light emitting diodes). In an embodiment, the second opaque rubber 208 comprises a black rubber or a grey rubber. For example, a material for the second opaque rubber 208 may comprise a silicone resin such as silicone, or an encapsulating material such as an epoxy resin, or other suitable materials. The first direction D1, the second direction D2 and the third direction D3 may be perpendicular to each other substantially. In an embodiment, the first direction D1 may be the X-axis direction, the second direction D2 may be the Z-axis direction, and the third direction D3 may be the Y-axis direction.

In an embodiment, the element disposition and/or the manufacturing method of the second display device 200 may be similar to or identical to the element disposition and/or the manufacturing method of the first display device 100. However, the present disclosure is not limited thereto. In another embodiment, the first display device 100 and the second display device 200 may be different in the element disposition and/or the manufacturing method.

Next, the first display device 100 and the second display device 200 are disposed on a substrate board 316, and the first display device 100 and the second display device 200 are stitched together. In an embodiment, the first circuit board 102 and the second circuit board 202 are adhered on the substrate board 316 through an adhesive layer, and the first display device 100 and the second display device 200 have a stitching seam 311 therebetween with no adhesive rubber at the stitching seam 311. In detail, the stitching seam 311 is defined between a rubber sidewall surface of the first outer border rubber portion 112L and a rubber sidewall surface of the second outer border rubber portion 212R facing to and adjacent to the rubber sidewall surface of the first outer border rubber portion 112L. There is no adhesion between the first outer border rubber portion 112L and the second outer border rubber portion 212R. The stitching seam 311 is also defined between a board sidewall surface of the first circuit board 102 and a board sidewall surface of the second circuit board 202 facing to and adjacent to the board sidewall surface of the first circuit board 102. There is no adhesion between the first circuit board 102 and the second circuit board 202. In an embodiment, the stitching seam 311 is formed by adjoining the first outer border rubber portion 112L and the second outer border rubber portion 212R, and/or is formed by adjoining the first circuit board 102 and the second circuit board 202. The stitching seam 311 may be an air space.

FIG. 5A shows a plan view of an embodiment as the first display device 100 and the second display device 200 are stitched together. FIG. 5 may be a cross-section view drawn along a CD section line in FIG. 5A. Referring to FIG. 5 and FIG. 5A, heights of the first spacer rubber portion and the first outer border rubber portion of the first display device 100 are identical to heights of the second spacer rubber portion and the second outer border rubber portion of the second display device 200. Otherwise, widths of the first spacer rubber portion 114₁₁, the first spacer rubber portion 114₁₂, the first spacer rubber portion 114₁₃, the first spacer rubber portion 114₂₁, the first spacer rubber portion 114₃₁, and the first spacer rubber portion 114₄₁ are identical to a total width of the first outer border rubber portion and the second outer border rubber portion. In other words, a width of each of the first spacer rubber portions is identical to a total of widths of the first outer border rubber portion and the second outer border rubber portion. In embodiments, upper surfaces of the first opaque rubber 108 and the second opaque rubber 208 are above upper surfaces of the light emitting units (such as the light emitting unit 104R, the light emitting unit 104G, the light emitting unit 104B, the light emitting unit 204R, the light emitting unit 204G, and the light emitting unit 204B), by which interference between adjacent display pixels can be avoided, and the visual perception at the stitching seam 311 can be improved.

In embodiments, a whole cross-sectional profile of the first outer border rubber portion and the second outer border rubber portion stitched together is identical to a cross-sectional profile of the adjacent first spacer rubber portion and a cross-sectional profile of the adjacent second spacer rubber portion, by which an substantial uniform optical effect can be provided to the display pixel adjacent to the stitching seam 311, and it also improves the visual perception at the stitching seam 311. For example, referring to FIG. 5, a cross-sectional profile of the first spacer rubber portion 114₁₁ may be identical to a whole cross-sectional profile of the first outer border rubber portion 112L and the second outer border rubber portion 212R disposed adjacent to the first outer border rubber portion 112L. The first spacer rubber portion 114₁₁, the first spacer rubber portion 114₁₂, the first spacer rubber portion 114₁₃, the second spacer rubber portion 214₁₁, the second spacer rubber portion 214₁₂, and the second spacer rubber portion 214₁₃ may have the same cross-sectional profile.

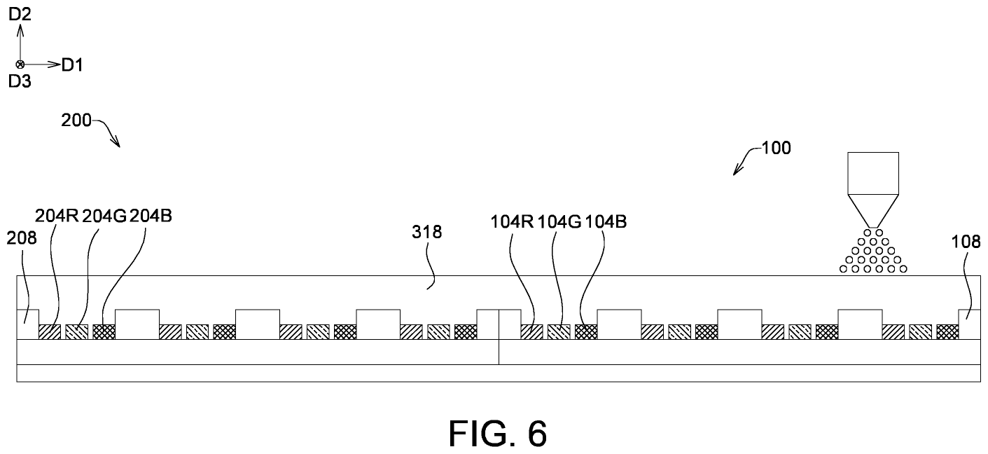

Referring to FIG. 6, a protecting layer 318 may be disposed on the first display device 100 and the second display device 200. The protecting layer 318 may cover the light emitting unit 104R, the light emitting unit 104G, and the light emitting unit 104B of the first display device 100, and the light emitting unit 204R, the light emitting unit 204G, and the light emitting unit 204B of the second display device 200. The protecting layer 318 may also cover on the first opaque rubber 108 of the first display device 100 and the second opaque rubber 208 of the second display device 200. The protecting layer 318 may be formed by disposing a curable rubber material by a spraying method, and then performing a curing step. The protecting layer 318 may be formed by other suitable methods, such as a coating method, an injecting method, etc. The protecting layer 318 can provide protection effect to the element covered by the protecting layer 318, avoiding influence from moisture, air, etc., for example.

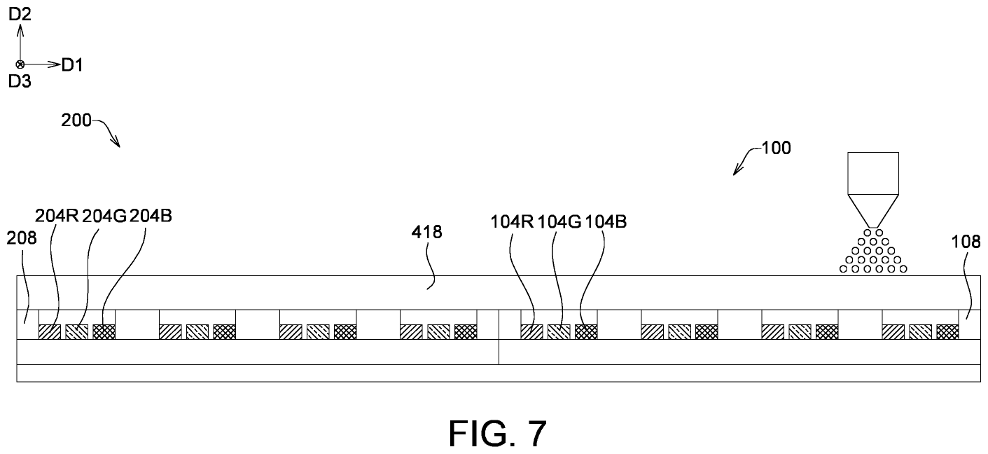

FIG. 7 illustrates a cross-section view of a display apparatus according to another embodiment, which is different from the display apparatus shown in FIG. 6 with the following description. A protecting layer 418 having a sheet shape is disposed on the upper surface of the first opaque rubber 108 and the upper surface of the second opaque rubber 208. A material of the protecting layer 418 may comprise a glass, or a plastic, etc., for example. There may be an air space between the protecting layer 418 and the light emitting unit 104R, the light emitting unit 104G, the light emitting unit 104B, the light emitting unit 204R, the light emitting unit 204G, and the light emitting unit 204B. The protecting layer 418 also can provide protection effect to the element (light emitting unit) covered by the protecting layer 418.

Accordingly, in the present invention, the first display device and the second display device are stitched together, and the first outer border rubber portion of the first display device and the second outer border rubber portion of the second display device are faced and adjacent to each other, by which the visual sensation resulted from the stitching seam can be reduced, and the display effect can be improved. Furthermore, the upper surfaces of the first opaque rubber and the second opaque rubber are above the upper surfaces of the light emitting units, by which interference between adjacent display pixels can be avoided, and the visual perception at the stitching seam can be improved.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display apparatus, comprising a first display device and a second display device, wherein the first display device comprises:
a first circuit board;
first display pixels electrically connected on the first circuit board; and
a first opaque rubber comprising a first outer border rubber portion and a first spacer rubber portion, wherein the first spacer rubber portion is in a gap space between the first display pixels, the first outer border rubber portion is outside the first display pixels,
the second display device comprises:
a second circuit board;
second display pixels electrically connected on the second circuit board; and
a second opaque rubber comprising a second outer border rubber portion, wherein the second outer border rubber portion is outside the second display pixels,
wherein the first display device and the second display device are stitched together, the first outer border rubber portion and the second outer border rubber portion are faced and adjacent to each other, the first spacer rubber portion, the first outer border rubber portion and the second outer border rubber portion have the same height.

2. The display apparatus according to claim 1, wherein the first spacer rubber portion has a width identical to a total width of the first outer border rubber portion and the second outer border rubber portion.

3. The display apparatus according to claim 1, wherein the first circuit board and the second circuit board have a stitching seam therebetween, there is no adhesive rubber at the stitching seam.

4. The display apparatus according to claim 3, further comprising a substrate board, wherein the first circuit board and the second circuit board are fastened on the substrate board.

5. The display apparatus according to claim 1, wherein a cross-sectional profile of the first spacer rubber portion is identical to a whole cross-sectional profile of the first outer border rubber portion and the second outer border rubber portion.

6. The display apparatus according to claim 1, wherein the first opaque rubber and the second opaque rubber are a black rubber.

7. The display apparatus according to claim 1, wherein the first outer border rubber portion and the second outer border rubber portion have a stitching seam therebetween, there is no adhesive rubber at the stitching seam.

8. The display apparatus according to claim 1, wherein each of the first display pixels and the second display pixels comprises light emitting units, the light emitting units comprise light emitting diodes, upper surfaces of the first opaque rubber and the second opaque rubber are above upper surfaces of the light emitting diodes.

9. The display apparatus according to claim 1, further comprising a protecting layer on the first opaque rubber and the second opaque rubber.

10. The display apparatus according to claim 1, further comprising a protecting layer, wherein each of the first display pixels and the second display pixels comprises light emitting units, the protecting layer is on the light emitting units.

11. A display apparatus, comprising a first display device and a second display device, wherein the first display device comprises:
a first circuit board;
first display pixels electrically connected on the first circuit board; and
a first opaque rubber comprising a first outer border rubber portion and a first spacer rubber portion, wherein the first spacer rubber portion is in a gap space between the first display pixels, the first outer border rubber portion is outside the first display pixels,
the second display device comprises:
a second circuit board;
second display pixels electrically connected on the second circuit board; and
a second opaque rubber comprising a second outer border rubber portion, wherein the second outer border rubber portion is outside the second display pixels,
wherein the first display device and the second display device are stitched together, the first outer border rubber portion and the second outer border rubber portion are faced and adjacent to each other, the first circuit board and the second circuit board have a stitching seam therebetween, there is no adhesive rubber at the stitching seam.

12. The display apparatus according to claim 11, wherein a cross-sectional profile of the first spacer rubber portion is identical to a whole cross-sectional profile of the first outer border rubber portion and the second outer border rubber portion.

13. The display apparatus according to claim 11, wherein the first opaque rubber and the second opaque rubber are a black rubber.

14. The display apparatus according to claim 11, wherein the first outer border rubber portion and the second outer border rubber portion have a stitching seam therebetween, there is no adhesive rubber at the stitching seam between the first outer border rubber portion and the second outer border rubber portion.

15. The display apparatus according to claim 11, wherein each of the first display pixels and the second display pixels comprises light emitting units, the light emitting units comprise light emitting diodes, upper surfaces of the first opaque rubber and the second opaque rubber are above upper surfaces of the light emitting diodes.

16. The display apparatus according to claim 11, further comprising a protecting layer on the first opaque rubber and the second opaque rubber.

17. The display apparatus according to claim 11, wherein the first spacer rubber portion has a width identical to a total width of the first outer border rubber portion and the second outer border rubber portion.

18. A manufacturing method for a display apparatus, comprising:
providing a first display device, wherein the first display device comprises:
a first circuit board;
first display pixels on the first circuit board; and
a first opaque rubber on the first circuit board, and comprising a first outer border rubber portion and a first spacer rubber portion, wherein the first spacer rubber portion is in a gap space between the first display pixels, the first outer border rubber portion is outside the first display pixels;
providing a second display device, wherein the second display device comprises:
a second circuit board;
second display pixels on the second circuit board; and
a second opaque rubber comprising a second outer border rubber portion, wherein the second outer border rubber portion is outside the second display pixels; and
stitching the first display device and the second display device together, wherein the first outer border rubber portion and the second outer border rubber portion are faced and adjacent to each other, and the first circuit board and the second circuit board are faced and adjacent to each other.

19. The manufacturing method for the display apparatus according to claim 18, wherein the first display device is formed by a method comprising:
disposing light emitting units on the first circuit board;
forming a mask on the light emitting units; and
disposing the first opaque rubber on a portion of the first circuit board not covered by the mask.

20. The manufacturing method for the display apparatus according to claim 18, further comprising disposing a protecting layer on the first opaque rubber and the second opaque rubber after the stitching the first display device and the second display device together.
